(19) United States
(12) Patent Application Publication
(10) Pub. No.: US 2024/0045198 A1
(43) Pub. Date: Feb. 8, 2024

(54) DRIVE ELEMENT AND LIGHT DEFLECTION ELEMENT

(71) Applicant: Panasonic Intellectual Property Management Co., Ltd., Osaka (JP)

(72) Inventor: Kensuke Mihara, Osaka (JP)

(21) Appl. No.: 18/381,970

(22) Filed: Oct. 19, 2023

Related U.S. Application Data
(63) Continuation of application No. PCT/JP2022/006579, filed on Feb. 18, 2022.

(30) Foreign Application Priority Data
Apr. 23, 2021 (JP) 2021-073526

(51) Int. Cl. G02B 26/08

(52) U.S. Cl. CPC G02B 26/0816

(57) ABSTRACT

A drive element includes: a pair of drive parts placed so as to be aligned in one direction; a movable part placed between the pair of drive parts; a pair of support parts placed such that the pair of drive parts and the movable part are interposed therebetween; a pair of connection parts connecting the pair of support parts to the movable part; and a fixing part connected to at least each of the pair of drive parts in an alignment direction of the drive parts. A resonance frequency of a drive body composed of the pair of drive parts and the pair of support parts and a resonance frequency of a movable body composed of the movable part and the pair of connection parts are substantially equal to each other.

### CROSS REFERENCE TO RELATED APPLICATION

This application is a continuation of International Application No. PCT/JP2022/006579 filed on Feb. 18, 2022, entitled “DRIVE ELEMENT AND LIGHT DEFLECTION ELEMENT”, which claims priority under 35 U.S.C. Section 119 of Japanese Patent Application No. 2021-073526 filed on Apr. 23, 2021, entitled “DRIVE ELEMENT AND LIGHT DEFLECTION ELEMENT”. The disclosures of the above applications are incorporated herein by reference.

### BACKGROUND OF THE INVENTION

### Field of the Invention

The present invention relates to a drive element that rotates a movable part about a rotation axis, and a light deflection element using the drive element.

### Description of Related Art

In recent years, by using micro electro mechanical system (MEMS) technology, drive elements that rotate a movable part have been developed. In this type of drive element, a reflection surface is located on the movable part, thereby allowing scanning to be performed at a predetermined deflection angle with light incident on the reflection surface. This type of drive element is installed in image display devices such as head-up displays and head-mounted displays. In addition, this type of drive element can also be used in laser radars that use laser beams to detect objects, etc.

“Shanshan Gu-Stoppel, Thorsten Giese, Hans-Joachim Quenzer, Ulrich Hofmann and Wolfgang Benecke, ‘PZT-Actuated and -Sensed Resonant Micromirrors with Large Scan Angles Applying Mechanical Leverage Amplification for Biaxial Scanning’, Micromachines, issued in 2017, Vol.8, Issue 7, P215” describes a drive element that rotates a mirror about a rotation axis by driving a pair of support parts parallel to each other. In the drive element, a drive part is placed at each of both ends of the pair of support parts. Both ends of the pair of support parts are driven up and down by these drive parts. Accordingly, torsion is generated at a connection part connecting the middles of the pair of support parts, so that a movable part located at the center of the connection part rotates. Thus, a mirror placed on the movable part rotates about the rotation axis defined by the connection part.

The drive element configured as described above has a simple configuration and thus can be easily formed. However, in the drive element, the rotation angle of the movable part per 1 Vpp is small, so that further improvement of the driving efficiency of the movable part is required.

### SUMMARY OF THE INVENTION

A first aspect of the present invention is directed to a drive element. The drive element according to this aspect includes: a pair of drive parts placed so as to be aligned in one direction; a movable part placed between the pair of drive parts; a pair of support parts placed such that the pair of drive parts and the movable part are interposed therebetween; a pair of connection parts connecting the pair of support parts to the movable part; and a fixing part connected to at least each of the pair of drive parts in an alignment direction of the drive parts. A resonance frequency of a drive body composed of the pair of drive parts and the pair of support parts and a resonance frequency of a movable body composed of the movable part and the pair of connection parts are substantially equal to each other.

In the drive element according to this aspect, the resonance frequency of the drive body and the resonance frequency of the movable body are substantially equal to each other. Accordingly, as shown in embodiments described later, the rotation angle of the movable part is increased, so that the driving efficiency of the movable part can be increased.

A second aspect of the present invention is directed to a light deflection element. The light deflection element according to this aspect includes the drive element according to the first aspect and a reflection surface located on the movable part.

Since the light deflection element according to this aspect includes the drive element according to the first aspect, the driving efficiency of the movable part can be increased. Therefore, the driving efficiency of the reflection surface can be increased, so that deflection of and scanning with light can be performed at a higher deflection angle.

The effects and the significance of the present invention will be further clarified by the description of the embodiments below. However, the embodiments below is merely an example for implementing the present invention. The present invention is not limited to the description of the embodiments below in any way.

### BRIEF DESCRIPTION OF THE DRAWINGS

FIG. 1 is a perspective view showing a configuration of a drive element according to Embodiment 1;

FIG. 2A is a plan view showing a configuration of a drive body according to Embodiment 1;

FIG. 2B is a plan view showing a movable body according to Embodiment 1;

FIG. 3A is a plan view schematically showing a line for obtaining displacement in a Z-axis direction in simulation according to Embodiment 1;

FIG. 3B to FIG. 3D are respectively graphs showing simulation results of examining displacement in the Z-axis direction according to Embodiment 1;

FIG. 4 is a simulation result showing a relationship between the ratio of the resonance frequency of the drive body to the resonance frequency of the movable body and the driving efficiency of the movable part in an in-phase mode according to Embodiment 1;

FIG. 5 is a simulation result showing a relationship between the ratio of the resonance frequency of the drive body to the resonance frequency of the movable body and the driving efficiency of the movable part in a reverse-phase mode according to Embodiment 1;

FIG. 6 is a simulation result showing a relationship between the ratio of the resonance frequency of the drive body to the resonance frequency of the movable body and the resonance frequency of the drive element in the in-phase mode and the reverse-phase mode according to Embodiment 1;

FIG. 7 is a perspective view showing a configuration of a drive element according to Embodiment 2;

FIG. 8 is a plan view showing the configuration of the drive element according to Embodiment 2;

FIG. 9 is a simulation result showing a relationship between the depth of each slit and the driving efficiency of a movable part according to Embodiment 2;

FIG. 10 is a simulation result showing a relationship between the ratio of the resonance frequency of a drive body to the resonance frequency of a movable body and the driving efficiency of the movable part in an in-phase mode according to Embodiment 2; and

FIG. 11 is a simulation result showing a relationship between the ratio of the resonance frequency of the drive body to the resonance frequency of the movable body and the driving efficiency of the movable part in a reverse-phase mode according to Embodiment 2.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Y-axis direction is a direction parallel to a rotation axis of a drive element, and the Z-axis direction is a direction perpendicular to a reflection surface located on a movable part.

### Embodiment 1

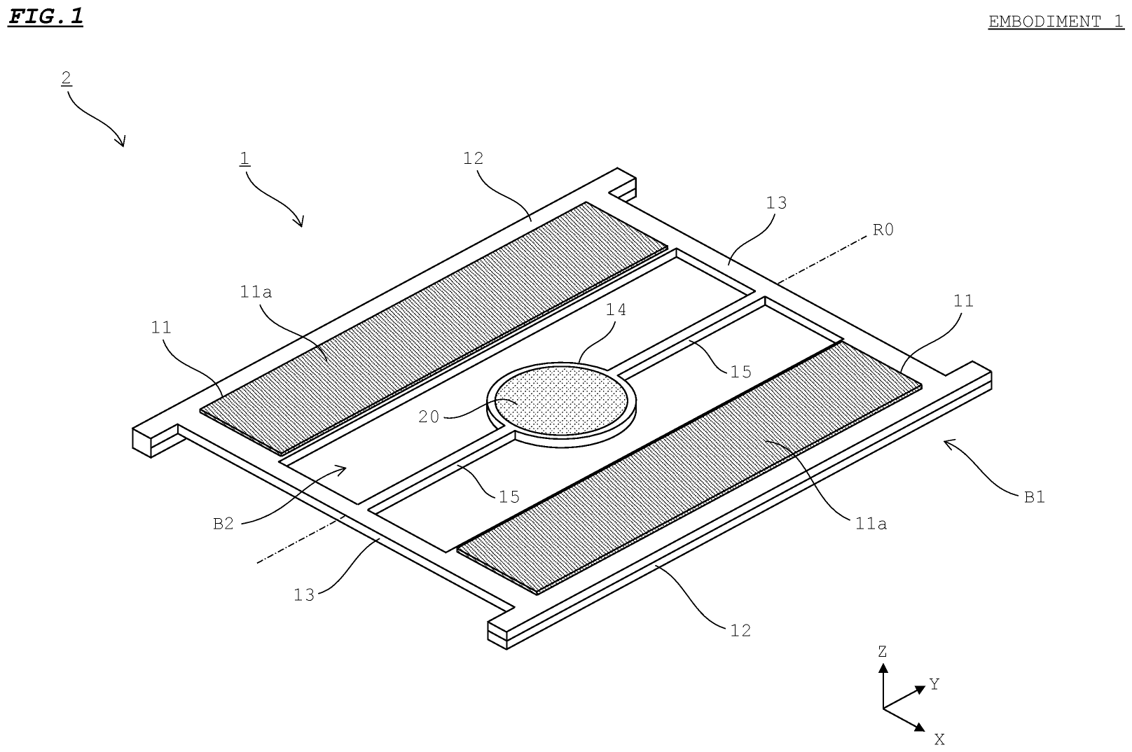

FIG. 1 is a perspective view showing a configuration of a drive element 1 according to Embodiment 1.

The drive element 1 includes a pair of drive parts 11, a pair of fixing parts 12, a pair of support parts 13, a movable part 14, and a pair of connection parts 15. A reflection surface 20 is located on the upper surface of the movable part 14, whereby a light deflection element 2 is configured. The drive element 1 has a symmetrical shape in the X-axis direction and the Y-axis direction in a plan view.

The pair of drive parts 11 are placed so as to be aligned in the X-axis direction. In a plan view, the shapes and the sizes of the pair of drive parts 11 are the same as each other. The shape of each drive part 11 is a rectangular shape in a plan view. The pair of drive parts 11 are placed such that ends on the inner side (movable part 14 side) thereof are parallel to the Y axis.

The pair of fixing parts 12 are placed such that the pair of drive parts 11 are interposed therebetween in the X-axis direction. The pair of fixing parts 12 have a constant width in the X-axis direction and extend parallel to the Y-axis direction. The drive element 1 is installed on an installation surface by installing the fixing parts 12 on the installation surface. The inner boundaries of the pair of fixing parts 12 are connected to the outer boundaries of the pair of drive parts 11 and the pair of support parts 13.

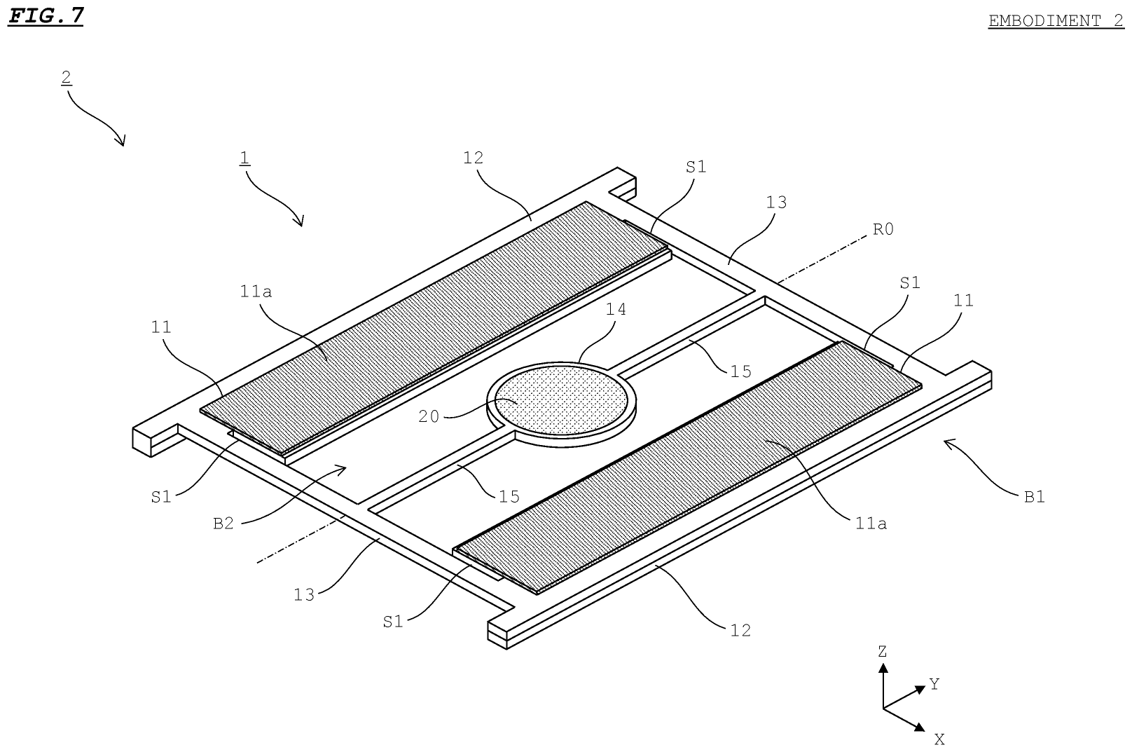

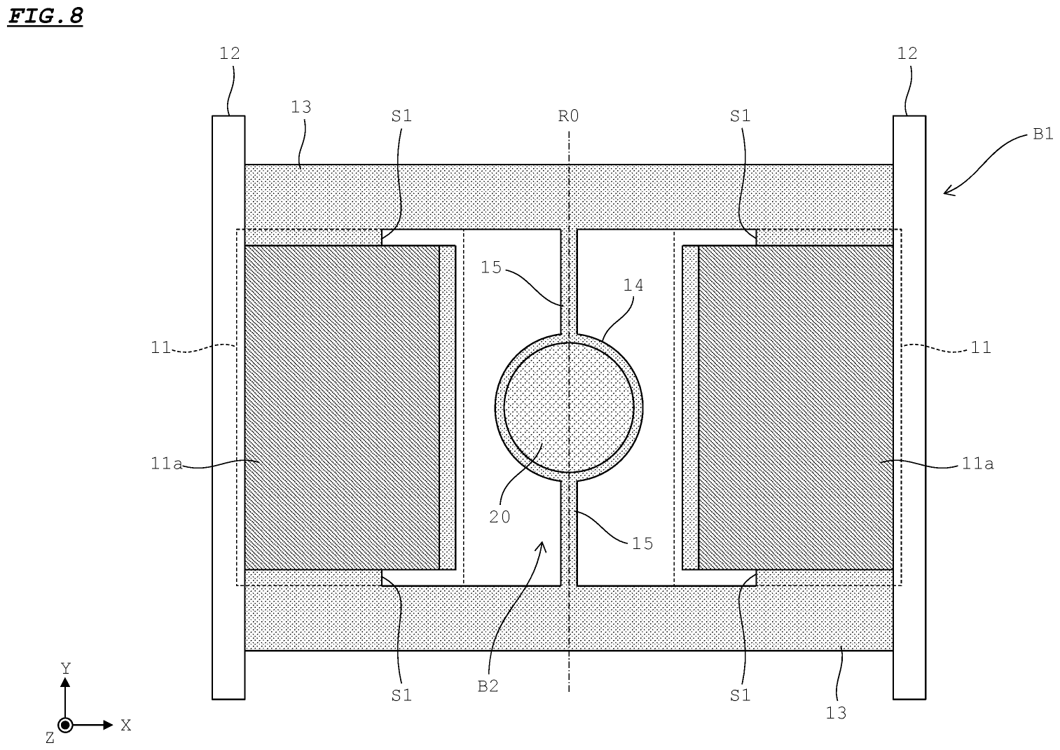

The pair of support parts 13 are placed such that the pair of drive parts 11 and the movable part 14 are interposed therebetween in the Y-axis direction. The pair of support parts 13 have a constant width in the Y-axis direction and extend parallel to the X-axis direction. The outer boundaries in the X-axis direction of the pair of support parts 13 are connected to the inner boundaries in the X-axis direction of the pair of fixing parts 12. In addition, end portions on both sides in the X-axis direction of the pair of support parts 13 are connected to the boundaries in the Y-axis direction of the pair of drive parts 11. Each drive part 11 is connected to each support part 13 over the entire width thereof in the X-axis direction. That is, in Embodiment 1, unlike Embodiment 2 described later, a slit S1 (see FIG. 7 and FIG. 8) extending in the X-axis direction is not provided between each support part 13 and each drive part 11.

The movable part 14 is placed between the pair of drive parts 11. In the X-axis direction, the center position of the movable part 14 coincides with the middle positions of the pair of drive parts 11. In the Y-axis direction, the center position of the movable part 14 coincides with the middle positions of the pair of support parts 13. Here, the shape of the movable part 14 is a circular shape in a plan view. The shape of the movable part 14 in a plan view may be a shape other than a circular shape, such as a square shape. The reflection surface 20 is located on the upper surface of the movable part 14. The reflection surface 20 is located on the upper surface of the movable part 14, for example, by forming a reflection film thereon by vapor deposition or the like. The reflection surface 20 may be formed by subjecting the upper surface of the movable part 14 to mirror finish.

The pair of connection parts 15 connect the pair of support parts 13 to the movable part 14. The pair of connection parts 15 extend in a straight manner Y-axis direction from the middle positions in the X-axis direction of the pair of support parts 13 toward the movable part 14 and are connected to the middle position in the X-axis direction of the movable part 14. The widths in the X-axis direction of the pair of connection parts 15 are constant. The lengths in the Y-axis direction of the pair of connection parts 15 are equal to each other. A cross-sectional shape of each connection part 15 when the connection part 15 is cut along a plane parallel to the X-Z plane is a rectangular shape whose upper side is parallel to the X-Y plane.

Piezoelectric drivers 11a are placed on the upper surfaces of the pair of drive parts 11. That is, the pair of drive parts 11 each include the piezoelectric driver 11a as a drive source. In a plan view, each piezoelectric driver 11a has a rectangular shape. The width of the piezoelectric driver 11a in the Y-axis direction is substantially equal to the width in the Y-axis direction of a portion, of the drive part 11, interposed between the boundaries on the movable part 14 side of the two support parts 13. In addition, the outer boundary of the piezoelectric driver 11a coincides with the inner boundary of the fixing part 12.

The piezoelectric driver 11a has a lamination structure in which electrode layers are placed on the upper and lower sides of a piezoelectric thin film having a predetermined thickness, respectively. The piezoelectric thin film is made of, for example, a piezoelectric material having a high piezoelectric constant, such as lead zirconate titanate (PZT). The electrode layers are made of a material having low electrical resistance and high heat resistance, such as platinum (Pt). The piezoelectric driver 11a is placed by forming the lamination structure, which includes the piezoelectric thin film and the electrode layers on the upper and lower sides thereof, on the upper surface of a substrate included in the region of the piezoelectric driver 11a by a sputtering method or the like.

A substrate of the drive element 1 has the same contour as the drive element 1 in a plan view, and has a constant thickness. The reflection surface 20 and the piezoelectric drivers 11a are placed in corresponding regions of the upper surface of the substrate. The thicknesses of the fixing parts 12 are increased by further stacking a predetermined material on the lower surfaces of portions, of the substrate, corresponding to the fixing parts 12. The material stacked at the fixing parts 12 may be a material different from that of the substrate, or may be the same material as that of the substrate. The substrate is, for example, integrally formed from silicon or the like. However, the material forming the substrate is not limited to silicon, and may be another material. The material forming the substrate is preferably a material having high mechanical strength and Young's modulus, such as metal, crystal, glass, and resin. As such a material, in addition to silicon, titanium, stainless steel, Elinvar, a brass alloy, etc., can be used. The same applies to the material stacked on the substrate at each fixing part 12.

The pair of drive parts 11 are curved in the Z-axis direction when a drive signal is supplied from a drive circuit which is not shown to the piezoelectric drivers 11a. Accordingly, the pair of support parts 13 are curved in the Z-axis direction. As a result, the connection parts 15 are twisted around a rotation axis R0, and the movable part 14 rotates about the rotation axis R0. Accordingly, the reflection surface 20 rotates about the rotation axis R0.

The reflection surface 20 reflects light incident thereon from above the movable part 14, in a direction corresponding to a deflection angle of the movable part 14. Accordingly, the light (e.g., laser beam) incident on the reflection surface 20 is deflected and scanning is performed with this light as the movable part 14 rotates.

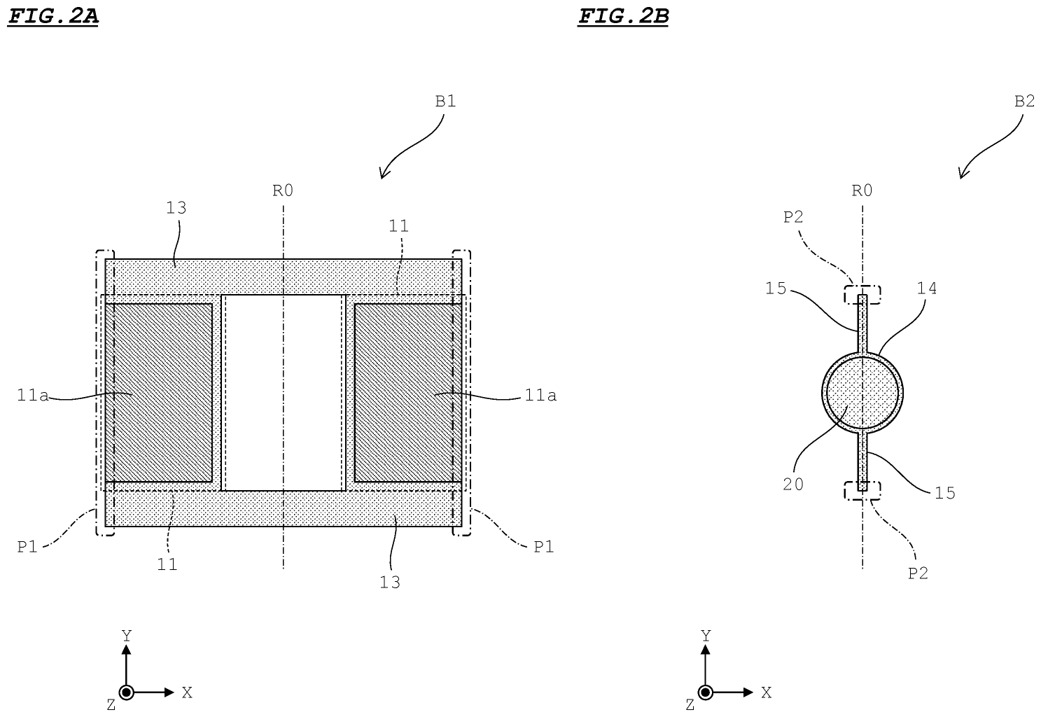

Here, the drive element 1 is configured such that the resonance frequency of a drive body B1 and the resonance frequency of a movable body B2 are substantially equal to each other in the drive element 1. As shown in FIG. 2A, the drive body B1 is composed of the pair of drive parts 11 and the pair of support parts 13 of the drive element 1. As shown in FIG. 2B, the movable body B2 is composed of the movable part 14, the pair of connection parts 15, and the reflection surface 20 of the drive element 1. That is, the movable body B2 is composed of the remainder of the driving element 1, excluding the drive body B1 and the pair of fixing parts 12.

A vibration mode targeted in identifying the resonance frequency of the drive body B1 is a mode in which a connection surface between the drive body B1 and each fixing part 12 (FIG. 1) is a fixed surface, directions of vibration in the Z-axis direction of the pair of drive parts 11 are opposite to each other, and the support parts 13 near the connection parts 15 (see FIG. 2B) rotationally vibrate around the rotation axis R0. In the configuration in FIG. 2A, each fixed surface of the drive body B1 is a surface P1 which is a combination of a connection surface between the drive part 11 and the fixing part 12 and a connection surface between each support part 13 and the fixing part 12. The surfaces P1 are parallel to the Y-Z plane and are located on the X-axis positive side and the X-axis negative side of the drive body B1 so as to correspond to the pair of fixing parts 12.

A vibration mode targeted in identifying the resonance frequency of the movable body B2 is a mode in which each connection surface between the movable body B2 and the drive body B1 is a fixed surface and the reflection surface 20 rotationally vibrates around the rotation axis R0. In the configuration in FIG. 2B, the fixed surfaces of the movable body B2 are surfaces P2 which are connection surfaces between the pair of connection parts 15 and the pair of support parts 13 (see FIG. 2A). The surfaces P2 are parallel to the X-Z plane and are located on the Y-axis positive side and the Y-axis negative side of the movable body B2 so as to correspond to the pair of connection parts 15.

When the resonance frequency of the drive body B1 and the resonance frequency of the movable body B2 are substantially equal to each other, the driving efficiency of the movable part 14 and the reflection surface 20 can be increased as described below.

Next, the fact that the driving efficiency of the movable part 14 and the reflection surface 20 can be increased by making the resonance frequency of the drive body B1 and the resonance frequency of the movable body B2 substantially equal to each other, will be described.

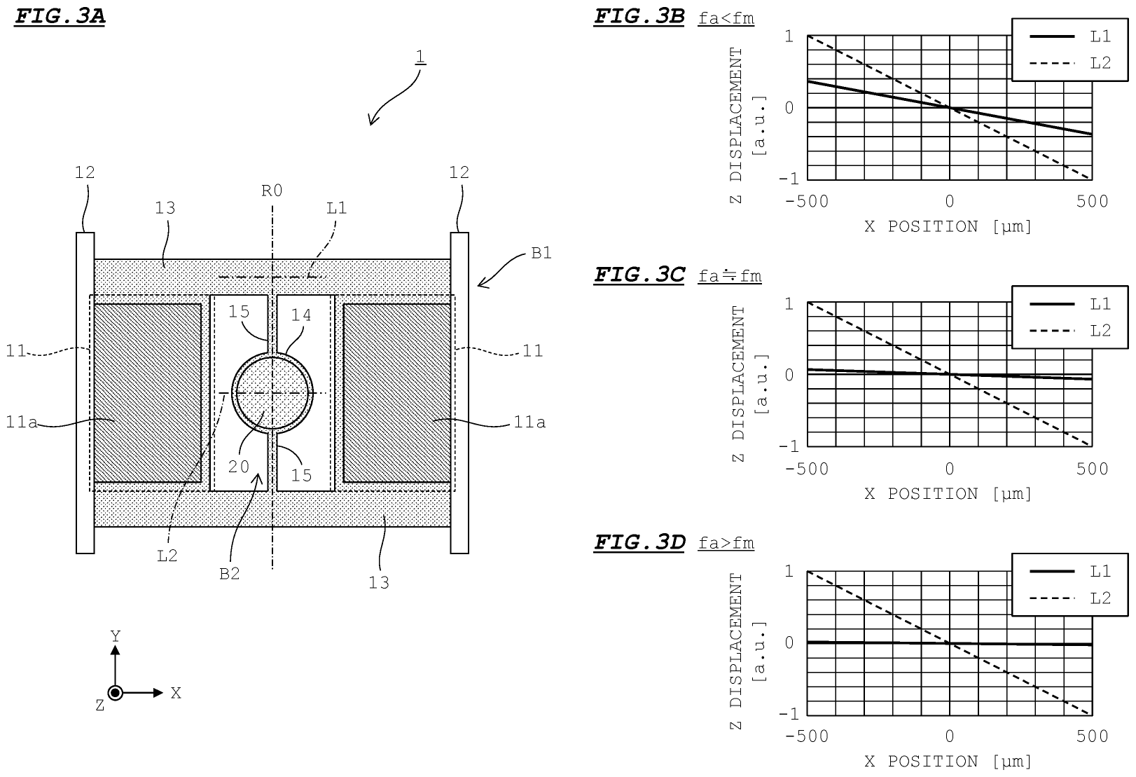

In simulation, the inventor drove the drive parts 11, and examined the displacement in the Z-axis direction of the support part 13 caused by the drive and the displacement in the Z-axis direction of the movable part 14 and the reflection surface 20 caused by the drive. As shown in FIG. 3A, the displacement in the Z-axis direction of the support part 13 is obtained along a line L1 extending in the X-axis positive direction and the X-axis negative direction from the center position in the X-axis direction and the Y-axis direction of the support part 13. In addition, the displacement in the Z-axis direction of the movable part 14 and the reflection surface 20 is obtained along a line L2 extending in the X-axis positive direction and the X-axis negative direction from the center of the movable part 14 and the reflection surface 20.

FIG. 3B to FIG. 3D are graphs showing the displacement in the Z-axis direction obtained by this simulation.

In each graph, the horizontal axis indicates the position along each line L1 or L2 (position in the X-axis direction). A value of 0 on the horizontal axis indicates the position of the rotation axis R0, a position in the X-axis positive direction is indicated by a positive value, and a position in the X-axis negative direction is indicated by a negative value. The vertical axis indicates the displacement amount in the Z-axis direction at each line L1 or L2. A value of on the vertical axis indicates the position when each drive part 11 is not driven. In addition, a value on the vertical axis is a value obtained by normalizing the value for each line L1 or L2 by the absolute value of the displacement amount when the position in the X-axis direction on the line L2 is +500 ∥m or −500 μm.

When the resonance frequency of the drive body B1 is denoted by fa and the resonance frequency of the movable body B2 is denoted by fm, FIG. 3B is a graph for the case of fa<fm, FIG. 3C is a graph for the case of fa≈fm, and FIG. 3D is a graph for the case of fa>fm.

In the case of FIG. 3B, the support part 13 is greatly deformed in the Z-axis direction when the movable part 14 and the reflection surface 20 are driven, so that it cannot be said that the movable part 14 and the reflection surface 20 are efficiently rotated. That is, in the case of FIG. 3B, the tilt of the movable body B2 is small with respect to the tilt formed by the drive body B1, so that a leverage ratio is small.

In contrast, in the case of FIG. 3C, the deformation of the support part 13 is smaller than in FIG. 3B, so that the movable part 14 and the reflection surface 20 are rotated more efficiently than in FIG. 3B. That is, in the case of FIG. 3C, the tilt of the movable body B2 is larger with respect to the tilt formed by the drive body B1 than in FIG. 3B, resulting in a larger leverage ratio. Moreover, in the case of FIG. 3D, the deformation of the support part 13 is even smaller than in FIG. 3C, so that the movable part 14 and the reflection surface 20 are rotated even more efficiently than in FIG. 3C. That is, in the case of FIG. 3D, the tilt of the movable body B2 is even larger with respect to the tilt formed by the drive body B1 than in FIG. 3C, resulting in an even larger leverage ratio.

Therefore, from the simulation results in FIG. 3B to FIG. 3D, it is found that the higher the resonance frequency fa of the drive body B1 is as compared to the resonance frequency fm of the movable body B2, the more efficiently the movable part 14 and the reflection surface 20 are rotated and the larger the leverage ratio is.

Here, it is generally known that there is a trade-off relationship between the resonance frequency of an actuator and the displacement amount of an object to be driven. That is, when the resonance frequency fa of the drive body B1 is low, the displacement amount of the movable part 14 and the reflection surface 20 is large. On the other hand, when the resonance frequency fa of the drive body B1 is high, the displacement amount of the movable part 14 and the reflection surface 20 is small. Therefore, when focusing on the relationship between the resonance frequency and the displacement amount, it can be said that the lower the resonance frequency fa of the drive body B1 is, the more efficiently the movable part 14 and the reflection surface 20 are rotated.

From the above examination and consideration, the inventor considered that for the ratio of the resonance frequency fa of the drive body B1 to the resonance frequency fm of the movable body B2, there is a range where the movable part 14 and the reflection surface 20 can be rotated most efficiently. Therefore, the inventor examined, by simulation, the rotation angle of the movable part 14 and the reflection surface 20 per 10 Vpp when a ratio R (=resonance frequency fa of drive body B1/resonance frequency fm of movable body B2) was changed around 1.

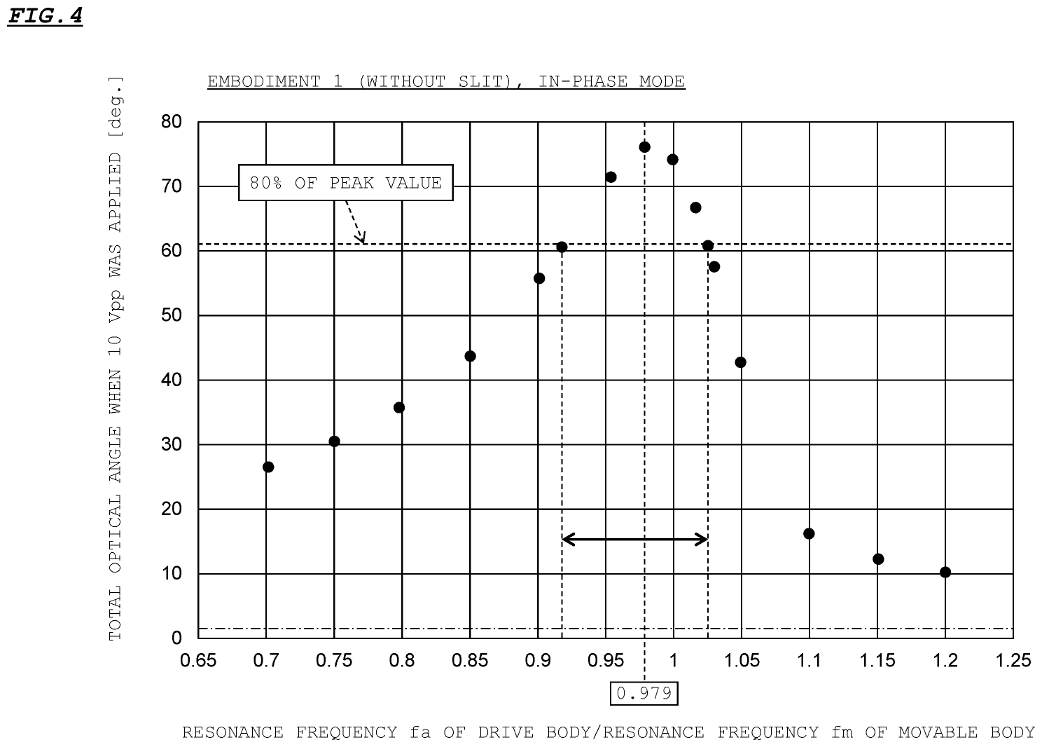

FIG. 4 is a graph showing a simulation result of the driving efficiency of the movable part 14 in a mode (hereinafter, referred to as “in-phase mode”) in which the direction of vibration of the drive body B1 and the direction of vibration of the movable body B2 are the same. In FIG. 4, the horizontal axis indicates the ratio R, and the vertical axis indicates the total of the rotation angle of the movable part 14 (reflection surface 20) per 10 Vpp.

In FIG. 4, the level (1° to 2°) of the rotation angle of the movable part 14 when the ratio R is about 4 is indicated by an alternate long and short dash line. As shown in FIG. 4, when the ratio R is not less than 0.7 and not greater than 1.2, that is, when the ratio R is substantially equal to 1, the rotation angle of the movable part 14 can be much larger than when the ratio R is about 4.

As shown in FIG. 4, when the ratio R was 0.979, the rotation angle of the movable part 14 had the largest value (76.11°). That is, when the ratio R of the resonance frequency fa of the drive body B1 to the resonance frequency fm of the movable body B2 was slightly lower than 1, the driving efficiency of the movable part 14 was highest.

In FIG. 4, a value that is 80% of the peak value) (76.11°) of the rotation angle is indicated by a dashed line. When the ratio R is not less than about 0.918 and not greater than about 1.025, the rotation angle is 80% or larger of the peak value of the rotation angle. Therefore, if the ratio R is set so as to be not less than 0.9 and not greater than 1.03, the rotation angle of the movable part 14 can be set sufficiently large, so that the driving efficiency of the movable part 14 can be increased.

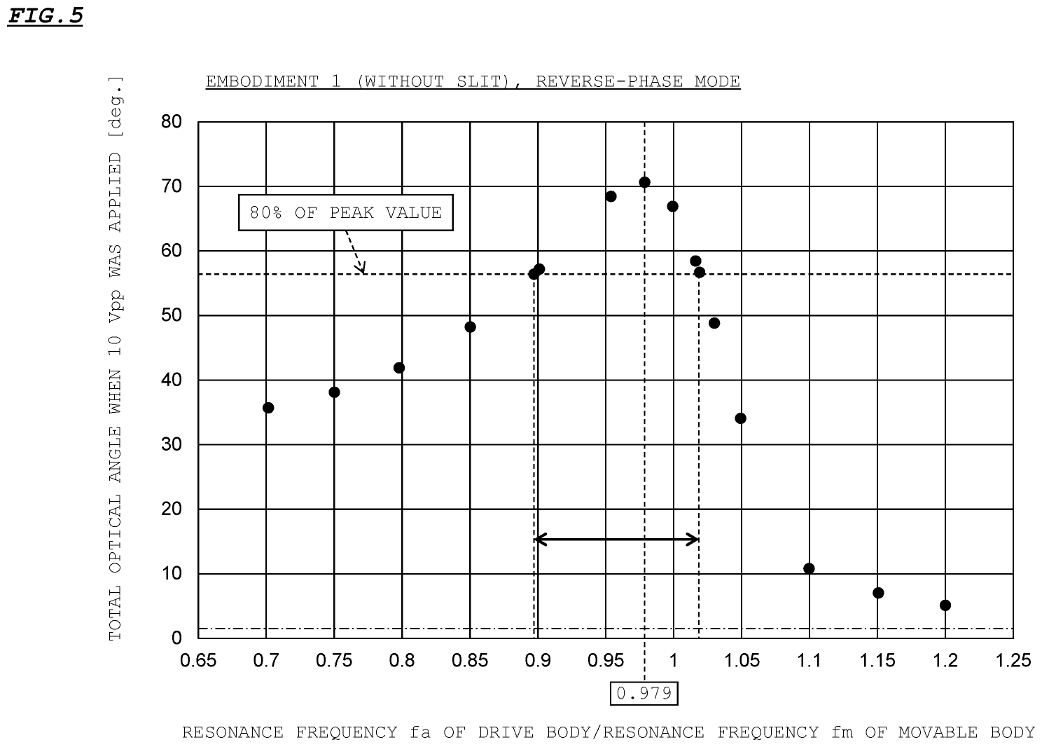

FIG. 5 is a graph showing a simulation result of the driving efficiency movable part 14 in a mode (hereinafter, referred to as “reverse-phase mode”) in which the direction of vibration of the drive body B1 and the direction of vibration of the movable body B2 are opposite to each other.

In FIG. 5, the level (1° to 2°) of the rotation angle of the movable part 14 when the ratio R is about 4 is indicated by an alternate long and short dash line. As shown in FIG. 5, when the ratio R is not less than 0.7 and not greater than 1.2, that is, when the ratio R is substantially equal to 1, the rotation angle of the movable part 14 can be much larger than when the ratio R is about 4.

As shown in FIG. 5, when the ratio R was 0.979, the rotation angle of the movable part 14 had the largest value) (70.64°). That is, when the ratio R of the resonance frequency fa of the drive body B1 to the resonance frequency fm of the movable body B2 was slightly lower than 1, the driving efficiency of the movable part 14 was highest.

In FIG. 5, a value that is 80% of the peak value (70.64°) of the rotation angle is indicated by a dashed line. When the ratio R is not less than about 0.897 and not greater than about 1.019, the rotation angle is 80% or larger of the peak value of the rotation angle. Therefore, if the ratio R is set so as to be not less than 0.9 and not greater than 1.03, the rotation angle of the movable part 14 can be sufficiently large, so that the driving efficiency of the movable part 14 can be increased.

From the simulation results in FIG. 4 and FIG. 5, it was found that the driving efficiency of the movable part 14 can be increased by configuring the drive element 1 such that the resonance frequency fa of the drive body B1 and the resonance frequency fm of the movable body B2 are substantially equal to each other. It was also found that in both the in-phase mode and the reverse-phase mode, the ratio R is preferably set in the range of not less than 0.9 and not greater than 1.03 and is even more preferably set around 0.98.

The inventor further examined, by simulation, the resonance frequency of the entire drive element 1 when the drive element 1 was configured such that the ratio R was a value around 1 in the in-phase mode and the reverse-phase mode.

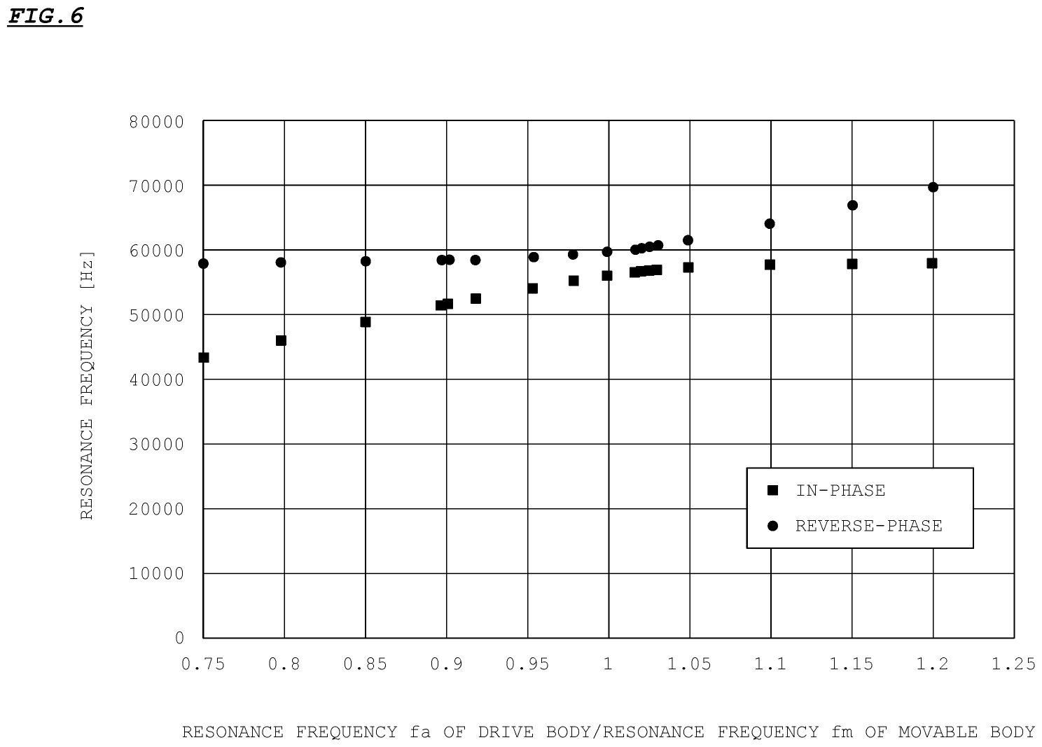

FIG. 6 is a graph showing a simulation result of the resonance frequency of the entire drive element 1 in the in-phase mode and the reverse-phase mode. In FIG. 6, the horizontal axis indicates the ratio R, and the vertical axis indicates the resonance frequency of the entire drive element 1.

In general, the resonance frequency of the entire element in the in-phase mode and the resonance frequency of the entire element in the reverse-phase mode are values distant from each other. In contrast, when the ratio R was set around 1 in the in-phase mode and the reverse-phase mode as described above, it was confirmed that the resonance frequency of the entire drive element 1 in the in-phase mode and the resonance frequency of the entire drive element 1 in the reverse-phase mode were values close to each other, as shown in FIG. 6.

### Effects of Embodiment 1

According to Embodiment 1, the following effects are achieved.

The resonance frequency fa of the drive body B1 composed of the pair of drive parts 11 and the pair of support parts 13 and the resonance frequency fm of the movable body B2 composed of the movable part 14 and the pair of connection parts are substantially equal to each other. Accordingly, as shown in FIG. 4 and FIG. 5, the rotation angle of the movable part 14 is increased, so that the driving efficiency of the movable part 14 can be increased. Therefore, deflection of and scanning with light can be performed at a higher deflection angle.

As shown in FIG. 4 and FIG. 5, by setting the ratio R of the resonance frequency fa of the drive body B1 to the resonance frequency fm of the movable body B2 to be not less than 0.9 and not greater than 1.03 in the in-phase mode and the reverse-phase mode, the rotation angle of the movable part 14 can be set to about 80% or larger of the peak value. Therefore, by setting the ratio R as described above, the driving efficiency of the movable part 14 can be increased.

As shown in FIG. 1, each drive part 11 includes the piezoelectric driver 11a as a drive source. Accordingly, the movable part 14 can be driven with high driving efficiency.

### Embodiment 2

In Embodiment 1, each drive part 11 is connected to each support part 13 over the entire width thereof in the X-axis direction. In contrast, in Embodiment 2, a slit S1 extending in the X-axis direction is provided between each support part 13 and each drive part 11.

FIG. 7 is a perspective view showing a configuration of a drive element 1 according to Embodiment 2, and FIG. 8 is a plan view showing the configuration of the drive element 1 according to Embodiment 2.

As shown in FIG. 7 and FIG. 8, a slit S1 is formed at each of both ends in the Y-axis direction of the pair of drive parts 11. The slits S1 are formed so as to extend outward from the ends on the inner side (movable part 14 side) of the pair of drive parts 11 by a predetermined length (depth). The slits S1 are formed by cutting the pair of drive parts 11 in a straight line from the ends on the inner side of the drive parts 11 toward the outer side. The widths and the lengths (depths) of the four slits S1 are equal to each other. Gaps are formed between the drive parts 11 and the support parts 13 by the four slits S1.

In Embodiment 2 as well, the drive body B1 is composed of the pair of drive parts 11 and the pair of support parts 13 of the drive element 1. The movable body B2 is composed of the movable part 14, the pair of connection parts 15, and the reflection surface 20 of the drive element 1. In addition, each fixed surface of the drive body B1 and each fixed surface of the movable body B2 are the same surfaces P1 and P2 as in Embodiment 1, respectively, as shown in FIG. 2A and FIG. 2B, and the vibration modes targeted in identifying the resonance frequencies of the drive body B1 and the movable body B2 are also the same as in Embodiment 1. In Embodiment 2 as well, the drive element 1 is configured such that the resonance frequency fa of the drive body B1 and the resonance frequency fm of the movable body B2 are substantially equal to each other.

In Embodiment 2, the slits S1 each having a predetermined length (depth) are formed near the boundaries between the pair of drive parts 11 and the pair of support parts 13, and the pair of drive parts 11 and the pair of support parts 13 are separated from each other at the positions of these slits S1. Accordingly, the driving efficiency of the movable part 14 and the reflection surface 20 can be made higher than in Embodiment 1.

Next, the inventor examined the relationship between the depth of each slit S1 in the X-axis direction and the driving efficiency of the movable part 14 by simulation.

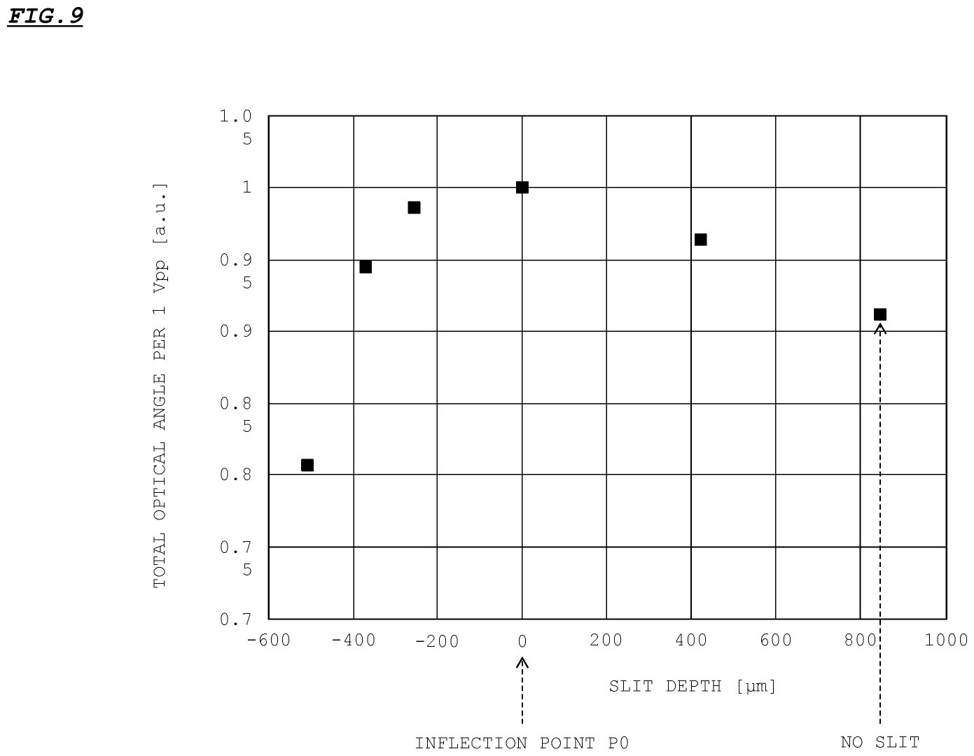

FIG. 9 shows a simulation result showing the relationship between the depth of each slit S1 and the driving efficiency of the movable part 14.

In FIG. 9, on the horizontal axis, the depth of the slit S1 is defined with the depth of the slit S1 as 0 in the case where the slit S1 extends to a position (inflection point P0) at which the gradient of the amplitude waveform of the support part 13 switches between increasing and decreasing. A positive value on the horizontal axis indicates a value at which the depth of the slit S1 decreases, and a negative value on the horizontal axis indicates a value at which the depth of the slit S1 increases. In FIG. 9, on the vertical axis, the total of the rotation angle of the movable part 14 (reflection surface 20) per 1 Vpp is indicated by a value normalized by the maximum value of the simulation result.

Here, the depth of the slit S1 (the value on the horizontal axis in FIG. 9) was changed to six types: −510 μm, −369 μm, −255 μm, 0 μm, 423 μm, and 846 μm. The plot at 846 μm on the horizontal axis corresponds to the case where the depth of the slit S1 is 0, that is, no slit S1 is formed as in Embodiment 1. The depth of the slit S1 in the case where the value on the horizontal axis is 0, that is, in the case where the slit S1 extends to the inflection point P0, is 846 μm.

As shown in FIG. 9, the driving efficiency of the movable part 14 gradually increased as the slit S1 became deeper. When the deepest position of the slit S1 corresponded to the position of the inflection point P0, the driving efficiency of the movable part 14 became the highest, and then the driving efficiency of the movable part 14 decreased as the slit S1 became deeper. When the depth of the slit S1 is excessively large as in the leftmost plot in FIG. 9, the driving efficiency of the movable part 14 became lower than that in the case where no slit S1 was provided (rightmost plot). Accordingly, it is confirmed that the depth of the slit S1 has a range suitable for improving the driving efficiency.

That is, in the examinaiton result in FIG. 9, it is confirmed that at least in the range to the depth corresponding to the second plot from the left, the driving efficiency of the movable part 14 becomes higher than that in the case where there is no slit S1. The depth (length in the X-axis direction) of the slit S1 corresponding to the second plot from the left is a depth extended by 369 μm from 864 μm, which is the depth of the slit S1 in the case where the slit S1 is extended to the inflection point P0. Therefore, from this examinaiton result, it is found that by setting the depth of the slit S1 in a range further to the depth larger by 44% (369 μm/846 μm) than the depth to the inflection point P0, the driving efficiency of the movable part 14 can be made higher than that in the case where there is no slit S1. In addition, from the examinaiton result in FIG. 9, it is also found that within this range, the depth to the inflection point P0 can increase the driving efficiency of the movable part 14 the most.

Therefore, from this examinaiton result, the depth of the slit S1 in the X-axis direction is preferably set within a range having, as an upper limit, a depth larger by about 40% than the depth to the inflection point P0, and is more preferably set to around the depth to the inflection point P0. Accordingly, the driving efficiency of the movable part 14 can be increased, and deflection of and scanning with light can be performed at a higher deflection angle by the reflection surface

Next, for the configuration of Embodiment 2, the inventor examined, by simulation, the rotation angle of the movable part 14 and the reflection surface 20 per 10 Vpp when a ratio R (=resonance frequency fa of drive body B1/resonance frequency fm of movable body B2) was changed around 1. In the following simulation, the drive element 1 was configured such that the depth of the slit S1 was positioned at the inflection point P0 when the ratio R of the resonance frequency fa of the drive body B1 to the resonance frequency fm of the movable body B2 was 1, and when the ratio R was varied, the depth of the slit S1 was fixed, and only the length in the X-axis direction of the support part 13 was changed.

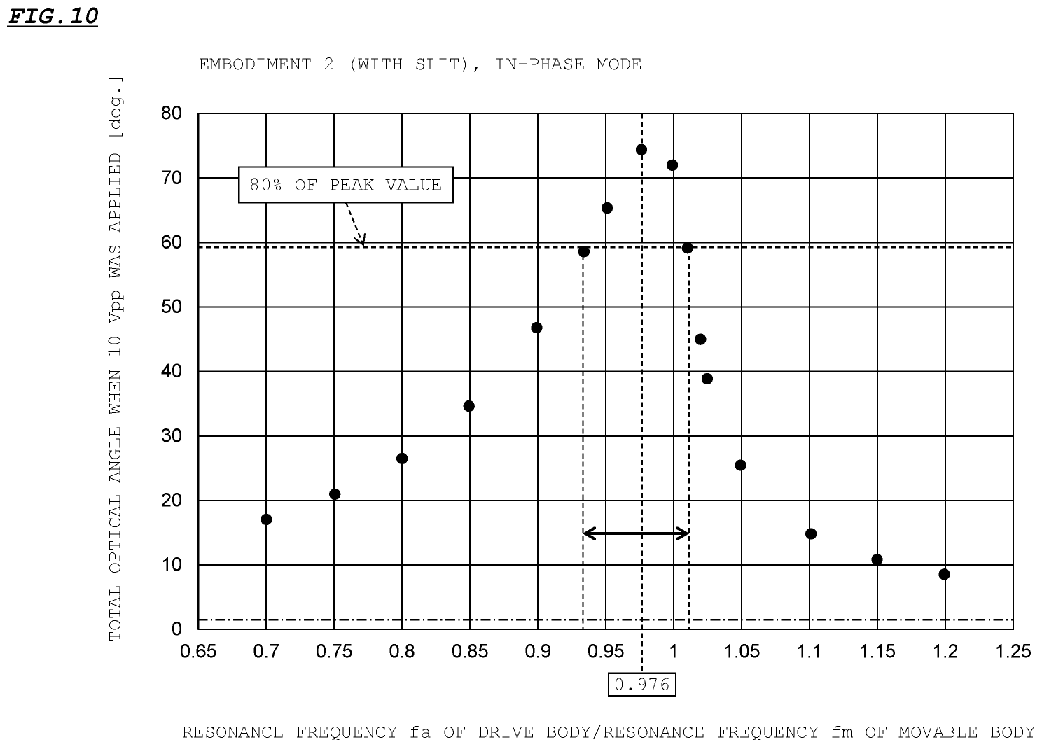

FIG. 10 is a graph showing a simulation result of the driving efficiency of the movable part 14 in the in-phase mode according to Embodiment 2.

In FIG. 10, the level (1° to 2°) of the rotation angle of the movable part 14 when the ratio R is about 4 is indicated by an alternate long and short dash line. As shown in FIG. 10, when the ratio R is not less than 0.7 and not greater than 1.2, that is, when the ratio R is substantially equal to 1, the rotation angle of the movable part 14 can be much larger than when the ratio R is about 4.

As shown in FIG. 10, when the ratio R was 0.976, the rotation angle of the movable part 14 had the largest value (74.39°). That is, when the ratio R of the resonance frequency fa of the drive body B1 to the resonance frequency fm of the movable body B2 was slightly lower than 1, the driving efficiency of the movable part 14 was highest.

In FIG. 10, a value that is 80% of the peak value (74.39°) of the rotation angle is indicated by a dashed line. When the ratio R is not less than about 0.934 and not greater than about 1.010, the rotation angle is 80% or larger of the peak value of the rotation angle. Therefore, if the ratio R is set so as to be not less than 0.9 and not greater than 1.02, the rotation angle of the movable part 14 can be set sufficiently large, so that the driving efficiency of the movable part 14 can be increased.

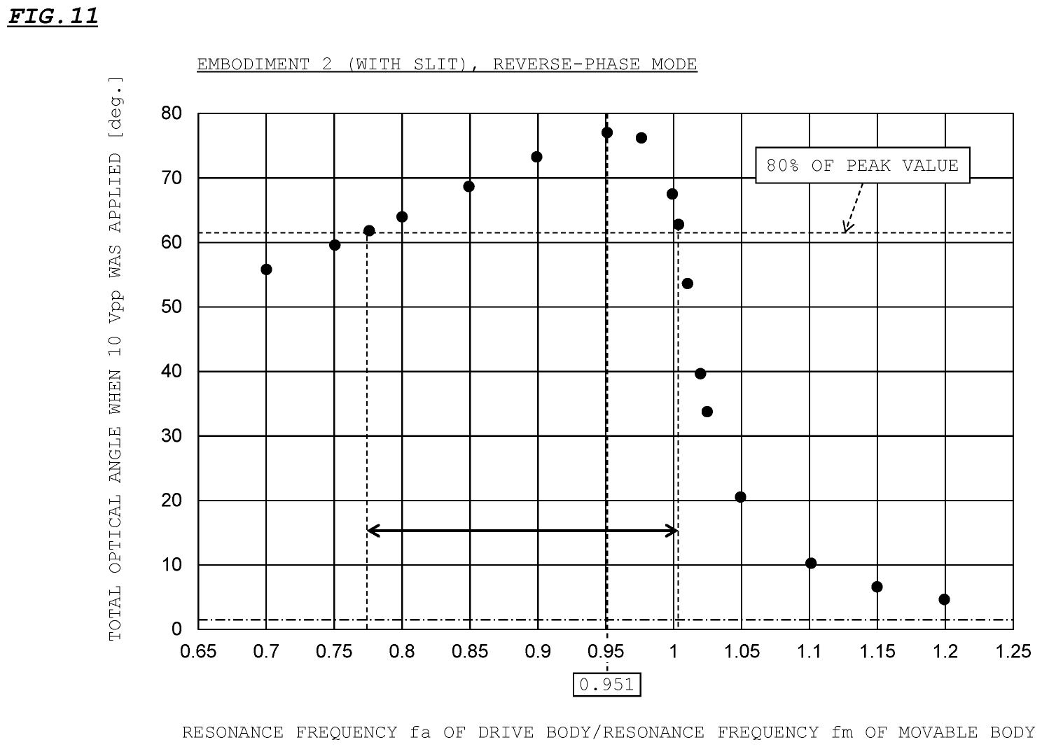

FIG. 11 is a graph showing a simulation result of the driving efficiency of the movable part 14 in the reverse-phase mode according to Embodiment 2.

In FIG. 11, the level (1° to 2°) of the rotation angle of the movable part 14 when the ratio R is about 4 is indicated by an alternate long and short dash line. As shown in FIG. 11, when the ratio R is not less than 0.7 and not greater than 1.2, that is, when the ratio R is substantially equal to 1, the rotation angle of the movable part 14 can be much larger than when the ratio R is about 4.

As shown in FIG. 11, when the ratio R was 0.951, the rotation angle of the movable part 14 had the largest value (77.05°). That is, when the ratio R of the resonance frequency fa of the drive body B1 to the resonance frequency fm of the movable body B2 was slightly lower than 1, the driving efficiency of the movable part 14 was highest.

In FIG. 11, a value that is 80% of the peak value (77.05°) of the rotation angle is indicated by a dashed line. When the ratio R is not less than about 0.776 and not greater than about 1.004, the rotation angle is 80% or larger of the peak value of the rotation angle. Therefore, if the ratio R is set so as to be not less than 0.7 and not greater than 1.01, the rotation angle of the movable part 14 can be sufficiently large, so that the driving efficiency of the movable part 14 can be increased.

From the simulation results in FIG. 10 and FIG. 11, it was found that the driving efficiency of the movable part 14 can be increased by configuring the drive element 1 such that the resonance frequency fa of the drive body B1 and the resonance frequency fm of the movable body B2 are substantially equal to each other. It was also found that in the in-phase mode, the ratio R is preferably set in the range of not less than 0.9 and not greater than 1.02 and is even more preferably set around 0.98. It was further found that in the reverse-phase mode, the ratio R is preferably set in the range of not less than 0.7 and not greater than 1.01 and is even more preferably set around 0.95

When the ratio R is set to any value around 1, the depth of the slit S1 is preferably set around the inflection point P0. Accordingly, from both aspects of the ratio R and the depth of the slit S1, the driving efficiency of the movable part 14 can be increased.

### Effects of Embodiment 2

According to Embodiment 2, the following effects are achieved.

In Embodiment 2 as well, the resonance frequency fa of the drive body B1 and the resonance frequency fm of the movable body B2 are substantially equal to each other. Accordingly, as shown in FIG. 10 and FIG. 11, the rotation angle of the movable part 14 is increased, so that the driving efficiency of the movable part 14 can be increased. Therefore, deflection of and scanning with light can be performed at a higher deflection angle.

As shown in FIG. 7 and FIG. 8, the pair of support parts 13 and the pair of drive parts 11 are separated from each other by the gaps (slits S1), and thus the curving of the support parts 13 at the positions of the gaps (slits S1) is not inhibited by the drive parts 11. In addition, the driving force of each drive part 11 generated around each gap (slit S1) is transmitted to the support part 13 via the connection range other than the gap (slit S1). Therefore, as shown in the examination result in FIG. 9, the support parts 13 can be more efficiently driven by the drive parts 11, so that the driving efficiency of the movable part 14 can be increased. As a result, the driving efficiency of the reflection surface 20 can be increased, so that deflection of and scanning with light can be performed at a higher deflection angle.

As shown in FIG. 7 and FIG. 8, the gaps are formed between the pair of support parts 13 and the pair of drive parts 11 by forming the slits S1 in the alignment direction of the pair of drive parts 11 (X-axis direction) from the ends on the movable part 14 side of the pair of drive parts 11. Accordingly, the gaps can be formed continuously from the ends on the movable part 14 side of the pair of drive parts 11, so that the driving efficiency of the movable part 14 can be smoothly increased.

As shown in FIG. 10, by setting the ratio R of the resonance frequency fa of the drive body B1 to the resonance frequency fm of the movable body B2 to be not less than 0.9 and not greater than 1.02 in the in-phase mode, the rotation angle of the movable part 14 can be set to about 80% or larger of the peak value. Therefore, by setting the ratio R as described above, the driving efficiency of the movable part 14 can be increased.

As shown in FIG. 11, by setting the ratio R of the resonance frequency fa of the drive body B1 to the resonance frequency fm of the movable body B2 to be not less than 0.7 and not greater than 1.01 in the reverse-phase mode, the rotation angle of the movable part 14 can be set to about 80% or larger of the peak value. Therefore, by setting the ratio R as described above, the driving efficiency of the movable part 14 can be increased.

### Modifications

In each of Embodiments 1 and 2 above, the shape of the drive element 1 in a plan view and the dimensions of each part of the drive element 1 can be changed as appropriate. The shape and the size of each piezoelectric driver 11a in a plan view can also be changed as appropriate. In addition, the thickness, the length, the width, and the shape of each fixing part 12 can also be changed as appropriate. For example, the thickness of each fixing part 12 may be equal to the thicknesses of each drive part 11 and each support part 13. The thickness, the width, and the shape of each fixing part 12 can be changed as appropriate as long as the drive element 1 can be installed on the installation surface.

In each of Embodiments 1 and 2 above, both ends of the pair of support parts 13 are connected to the pair of fixing parts 12, but both ends of the support parts 13 do not have to be connected to the fixing parts 12. For example, the width in the Y-axis direction of each fixing part 12 may be set to be equal to the width in the Y-axis direction of each drive part 11, and both end portions of the support parts 13 may be connected to only both edges in the Y-axis direction of the drive parts 11. In this case, each fixed surface of the drive body B1 is the connection surface between the drive part 11 and the fixing part 12.

In each of Embodiments 1 and 2 above, both ends in the Y-axis direction of one fixing part 12 and both ends in the Y-axis direction of the other fixing part 12 may be connected in the X-axis direction to form a fixing part. That is, a fixing part 12 may be formed so as to surround the pair of drive parts 11 and the pair of support parts 13 in a plan view.

In Embodiment 2 above, the gap is formed between each drive part 11 and each support part 13 by continuously forming the slit S1 having a constant width in the Y-axis direction, but the method for forming the gap is not limited thereto. For example, the width in the Y-axis direction of the gap may be changed depending on the position in the X-axis direction by changing the width of the drive part 11 or the support part 13 in the X-axis direction. The gap does not have to be continuous in the X-axis direction, and may be formed intermittently in the X-axis direction. However, in order to further increase the driving efficiency of the movable part 14, it is preferable that the gap is formed continuously in the X-axis direction from the end on the movable part 14 side of the drive part 11 as in the above embodiment.

As described above, even when the thickness, the length, the width, and the shape of each part of the driving element 1 are changed as appropriate, the drive body B1 is composed of the pair of drive parts 11 and the pair of support parts 13, and the movable body B2 is composed of the movable part 14, the pair of connection parts 15, and the reflection surface 20. The drive element 1 is configured such that the resonance frequency fa of the drive body B1 and the resonance frequency fm of the movable body B2 are substantially equal to each other. Accordingly, the driving efficiency of the movable part 14 and the reflection surface 20 can be increased.

The drive element 1 may be used as an element other than the light deflection element 2. In the case where the drive element 1 is used as an element other than the light deflection element 2, the reflection surface 20 does not have to be placed on the movable part 14, and a member other than the reflection surface 20 may be placed thereon. In this case, the movable body B2 is composed of the movable part 14, the pair of connection parts 15, and the other member.

In addition to the above, various modifications can be made as appropriate to the embodiments of the present invention, without departing from the scope of the technological idea defined by the claims.

What is claimed is:

1. A drive element comprising:
a pair of drive parts placed so as to be aligned in one direction;
a movable part placed between the pair of drive parts;
a pair of support parts placed such that the pair of drive parts and the movable part are interposed therebetween;
a pair of connection parts connecting the pair of support parts to the movable part; and
a fixing part connected to at least each of the pair of drive parts in an alignment direction of the drive parts, wherein
a resonance frequency of a drive body composed of the pair of drive parts and the pair of support parts and a resonance frequency of a movable body composed of the movable part and the pair of connection parts are substantially equal to each other.

2. The drive element according to claim 1, wherein each drive part is connected to each support part over an entire width thereof in the alignment direction of the drive parts.

3. The drive element according to claim 2, wherein a ratio of the resonance frequency of the drive body to the resonance frequency of the movable body is not less than 0.9 and not greater than 1.03.

4. The drive element according to claim 1, wherein
both end portions of the pair of support parts are connected to the pair of drive parts, respectively, and
gaps each having a predetermined length are provided between the pair of support parts and the pair of drive parts so as to extend in the alignment direction of the drive parts.

5. The drive element according to claim 4, wherein a ratio of the resonance frequency of the drive body to the resonance frequency of the movable body is not less than 0.9 and not greater than 1.02 in a mode in which a direction of vibration of the movable body and a direction of vibration of the drive body are the same.

6. The drive element according to claim 4, wherein a ratio of the resonance frequency of the drive body to the resonance frequency of the movable body is not less than 0.7 and not greater than 1.01 in a mode in which a direction of vibration of the movable body and a direction of vibration of the drive body are opposite to each other.

7. The drive element according to claim 1, wherein each drive part includes a piezoelectric driver as a drive source.

8. A light deflection element comprising:
a drive element; and
a reflection surface located on a movable part, wherein the drive element includes
a pair of drive parts placed so as to be aligned in one direction,
the movable part placed between the pair of drive parts,
a pair of support parts placed such that the pair of drive parts and the movable part are interposed therebetween,
a pair of connection parts connecting the pair of support parts to the movable part, and
a fixing part connected to at least each of the pair of drive parts in an alignment direction of the drive parts, and
a resonance frequency of a drive body composed of the pair of drive parts and the pair of support parts and a resonance frequency of a movable body composed of the movable part and the pair of connection parts are substantially equal to each other.

9. The light deflection element according to claim 8, wherein each drive part is connected to each support part over an entire width thereof in the alignment direction of the drive parts.

10. The light deflection element according to claim 9, wherein a ratio of the resonance frequency of the drive body to the resonance frequency of the movable body is not less than 0.9 and not greater than 1.03.

11. The light deflection element according to claim 8, wherein
both end portions of the pair of support parts are connected to the pair of drive parts, respectively, and
gaps each having a predetermined length are provided between the pair of support parts and the pair of drive parts so as to extend in the alignment direction of the drive parts.

12. The light deflection element according to claim 11, wherein a ratio of the resonance frequency of the drive body to the resonance frequency of the movable body is not less than and not greater than 1.02 in a mode in which a direction of vibration of the movable body and a direction of vibration of the drive body are the same.

13. The light deflection element according to claim 11, wherein a ratio of the resonance frequency of the drive body to the resonance frequency of the movable body is not less than 0.7 and not greater than 1.01 in a mode in which a direction of vibration of the movable body and a direction of vibration of the drive body are opposite to each other.

14. The light deflection element according to claim 8, wherein each drive part includes a piezoelectric driver as a drive source.
